(19) United States
(12) Patent Application Publication
(10) Pub. No.: US 2023/0238256 A1
(43) Pub. Date: Jul. 27, 2023

(54) APPARATUS FOR PROCESSING WAFER AND METHOD FOR CONTROLLING PROCESSING OF WAFER

(71) Applicant: CHANGXIN MEMORY TECHNOLOGIES, INC., Hefei City (CN)

(72) Inventors: Jianzhong DING, Hefei (CN); Xiaofeng Zhu, Hefei (CN); Ning Xi, Hefei (CN)

(21) Appl. No.: 17/830,580

(22) Filed: Jun. 2, 2022

Related U.S. Application Data
(63) Continuation of application No. PCT/CN2022/075846, filed on Feb. 10, 2022.

(30) Foreign Application Priority Data
Jan. 27, 2022 (CN) 202210101281.4

(51) Int. Cl. H01L 21/67

(52) U.S. Cl. CPC H01L 21/67034

(57) ABSTRACT

An apparatus for processing a wafer is provided. The provided apparatus for processing a wafer includes a chamber, a first nozzle, a negative pressure chamber and a vacuum pump. The first nozzle is arranged in the chamber and configured to spray a drying agent to the wafer. The negative pressure chamber is located in the chamber. The vacuum pump is located outside of the chamber and connected with the negative pressure chamber through a pipeline. The negative pressure chamber is arranged in a direction perpendicular to the wafer, and a gas in the negative pressure chamber is sucked by the vacuum pump through the pipeline to generate a negative pressure in the chamber, so as to reduce a surface pressure of the drying agent sprayed onto the wafer by the first nozzle. A method for controlling processing of a wafer is also provided.

### CROSS-REFERENCE TO RELATED APPLICATIONS

This application is a U.S. Continuation Application of International Application No. PCT/CN2022/075846, filed on Feb. 10, 2022 and entitled “APPARATUS FOR PROCESSING WAFER AND METHOD FOR CONTROLLING PROCESSING OF WAFER”, which claims priority to Chinese Patent Application No. 202210101281.4, filed on Jan. 27, 2022 and entitled “APPARATUS FOR PROCESSING WAFER AND METHOD FOR CONTROLLING PROCESSING OF WAFER”. The entire contents of International Application No. PCT/CN2022/075846 and Chinese Patent Application No. 202210101281.4 are incorporated herein by reference.

### BACKGROUND

Dynamic Random Access Memory (DRAM) is a semiconductor memory applied extensively to a computer system. With constant decrease of characteristic sizes of devices of a semiconductor integrated circuit (IC) and increase of depth-to-width ratios of the devices, pattern collapse is easily to occur during drying, affecting yield of wafer.

### SUMMARY

The disclosure relates to the technical field of semiconductors, and in particular to an apparatus for processing a wafer and a method for controlling processing of a wafer.

Embodiments of the disclosure provide an apparatus for processing a wafer and a method for controlling processing of a wafer, to avoid pattern collapse during drying when the wafer is processed, thereby improving yield of the wafer.

An embodiment of the disclosure provides an apparatus for processing a wafer, including a first chamber, a first nozzle, a negative pressure chamber and a vacuum pump.

The first nozzle is arranged in the first chamber and configured to spray a drying agent to the wafer.

The negative pressure chamber is located in the first chamber.

The vacuum pump is located outside of the first chamber and connected with the negative pressure chamber through a pipeline.

The negative pressure chamber is arranged in a direction perpendicular to the wafer, and a gas in the negative pressure chamber is sucked by the vacuum pump through the pipeline to generate a negative pressure in the first chamber, so as to reduce a surface pressure of the drying agent sprayed onto the wafer by the first nozzle.

An embodiment of the disclosure provides a method for controlling processing of a wafer, implemented based on any apparatus as described above and including the following operations.

The vacuum pump of the apparatus is controlled to be started.

Change of positions of the first nozzle, the second nozzle and the negative pressure chamber of the apparatus is controlled according to a preset parameter list.

Another embodiment of the disclosure provides a computing device, including a memory and a processor. The memory may be configured to store program instructions. The processor may be configured to call the program instructions stored in the memory, to execute, according to an obtained program, any method as described above.

Furthermore, a computer program product for a computer is provided for example according to an embodiment, the product includes a software code part. When the product is operated on a computer, the software code part executes operations of the method as defined above. The computer program product may include a computer-readable medium having stored thereon a software code part. Furthermore, the computer program product may be directly loaded into an internal memory of the computer and/or sent out, by a network through at least one of an uploading process, a downloading process, or a pushing process.

Another embodiment of the disclosure provides a computer-readable storage medium, having stored thereon computer-executable instructions. The computer-executable instructions enable a computer to execute any method as described above.

### BRIEF DESCRIPTION OF THE DRAWINGS

In order to describe technical solutions of embodiments of the disclosure more clearly, drawings required to be used in descriptions of the embodiments will be briefly introduced below. It is apparent that the drawings as described below are merely some embodiments of the disclosure, and other drawings may also be obtained from these drawings by those of ordinary skill in the art without paying any creative work.

FIG. 1 is a schematic curve diagram of a relationship between a boiling point of a drying agent and pressure according to an embodiment of the disclosure.

FIG. 2 is a schematic structural diagram of an apparatus for processing a wafer according to an embodiment of the disclosure.

FIG. 3 is a schematic structural diagram of a negative pressure chamber according to an embodiment of the disclosure.

FIG. 4 is a schematic structural diagram of an apparatus for processing a wafer according to an embodiment of the disclosure.

FIG. 5A is a schematic diagram of an LED layout according to an embodiment of the disclosure.

FIG. 5B is a schematic top view of the LED layout corresponding to FIG. 5A.

FIG. 6 is a schematic diagram of a preset parameter list required by a wafer processing process according to an embodiment of the disclosure.

FIG. 7 is a schematic diagram of switching a negative pressure chamber, a first nozzle and a second nozzle between their respective initial positions and working positions according to an embodiment of the disclosure.

FIG. 8 is a schematic flowchart of a method for controlling processing of a wafer according to an embodiment of the disclosure.

FIG. 9 is a schematic structural diagram of an apparatus for controlling processing of a wafer according to an embodiment of the disclosure.

### DETAILED DESCRIPTION

The technical solutions in the embodiments of the disclosure will be described clearly and completely below in combination with the drawings in the embodiments of the disclosure. It is apparent that the described embodiments are part of the embodiments of the disclosure, rather than all of the embodiments. All other embodiments obtained by those of ordinary skill in the art based on the embodiments of the disclosure without paying any creative work shall fall within the scope of protection of the disclosure.

The embodiments of the disclosure provide an apparatus for processing a wafer and a method for controlling processing of a wafer, to avoid pattern collapse during drying when the wafer is processed, thereby improving yield of the wafer.

The method and the apparatus are based on the same inventive concept. Since the method and the apparatus solve problems based on similar principles, implementations of the apparatus and the method may refer to each other, and repetitions will not be elaborated.

Terms “first”, “second”, or the like (if any) referred in the description, claims and the drawings of the embodiments of the disclosure are intended to distinguish similar objects, rather than intended to describe a specific ranking or order. It may be understood that data used as such may be interchanged as appropriate, so that the embodiments described here may be implemented in an order other than the contents illustrated or described here. Furthermore, terms “include”, “have” as well as any variations thereof are intended to cover non-exclusive inclusion, for example, a process, method, system, product or server including a series of operations or units is not limited to those operations or units which are listed clearly, and may include other operations or units which are not listed clearly or inherent to these processes, methods, products or devices.

The following examples and embodiments are understood as descriptive examples only. Although “an”, “one”, or “some” examples or embodiments may be mentioned in the description for many times, it does not mean that every mention is related to the same example or embodiment, and it does not mean that this feature is only applicable to a single example or embodiment either. Single features of different embodiments may also be combined to provide other embodiments. Furthermore, terms such as “include” and “comprise” should be understood as not limiting the described embodiments to be formed by those mentioned features only. Such examples and embodiments may further include features, structures, units, modules, or the like which are not mentioned specifically.

The embodiments of the disclosure will be described in detail below in combination with the drawings of the description. It should be noted that sequences of presentation of the embodiments of the disclosure only represent sequential orders of the embodiments and do not represent superiority-inferiority of the technical solutions provided in the embodiments.

In the embodiments of the disclosure, a negative pressure device is additionally arranged to reduce pressure, such that a boiling point of Isopropyl Alcohol (IPA) is reduced, IPA is easier to vaporize, furthermore, a surface tension is reduced. Therefore, a probability of reducing pattern collapse is achieved.

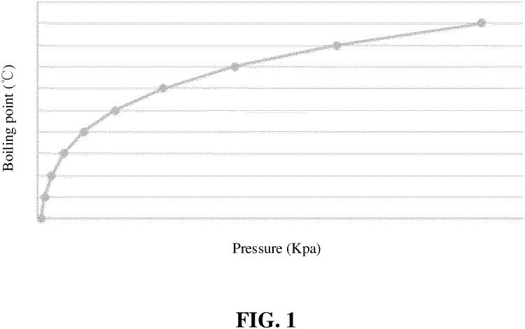

As shown in FIG. 1, it may be seen from a curve of a relationship between a boiling point of a drying agent and pressure that the boiling point of the drying agent may be reduced by reducing the pressure, to make the drying agent easier to vaporize.

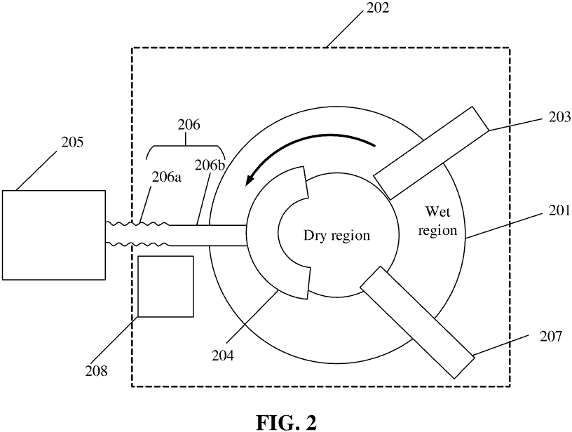

Therefore, referring to FIG. 2, an embodiment of the disclosure provides an apparatus for processing a wafer 201, including a first chamber 202, a first nozzle 203, a negative pressure chamber 204 and a vacuum pump 205.

The first nozzle 203 is arranged in the first chamber 202 and configured to spray a drying agent to the wafer 201.

In the embodiment of the disclosure, the drying agent is a volatile solvent with characteristics of a low boiling point, dissolving in water and a low surface tension. In the embodiment of the disclosure, the drying agent may be IPA, or may be methanol, ethanol, or the like besides IPA. The drying agent has characteristics of a low boiling point, dissolving in water and a low surface tension.

The negative pressure chamber 204 is located in the first chamber 202.

The vacuum pump 205 is located outside of the first chamber 202 and connected with the negative pressure chamber 204 through a pipeline 206.

The negative pressure chamber 204 is arranged in a direction perpendicular to the wafer 201, and a gas in the negative pressure chamber 204 is sucked by the vacuum pump 205 through the pipeline 206 to generate a negative pressure in the first chamber 202, so as to reduce a surface pressure of the drying agent sprayed onto the wafer 201 by the first nozzle 203.

In the embodiment of the disclosure, a negative pressure device, i.e., the negative pressure chamber, is additionally arranged in the first chamber, to reduce surface pressure of the drying agent and make the drying agent easier to vaporize. Therefore, a capillary force during drying is reduced, and a probability of reducing pattern collapse is achieved.

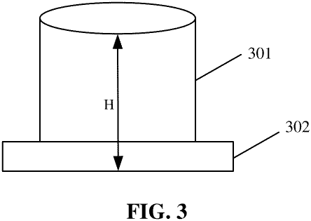

In an embodiment, further referring to FIG. 3, the negative pressure chamber 204 may include a first part 301 and a second part 302, the first part 301 is located above the second part 302 in the direction perpendicular to the wafer 201, and a projection region of the first part 301 is located within a projection region of the second part 302 in a direction parallel to the wafer 201. In a top view, each of the first part 301 and the second part 302 is shaped in an arc (as shown in FIG. 2) and concentric with the wafer 201. An arc radius of the first part 301 is smaller than that of the second part 302. The second part 302 may also be referred to as an outward-extending cover. A specific example is as follows.

In a top view, the negative pressure chamber 204 is shaped in an arc and concentric with the wafer 201. In a front view, as shown in FIG. 3, the first part 301 of the negative pressure chamber 204 is shaped in cylinder, and an outward-extending cover is arranged at a lower edge of the negative pressure chamber 204. In a front view, the outward-extending cover is shaped in cylinder. A width of the first part 301 at an upper portion of the negative pressure chamber 204 ranges from 15 to 40 mm. A height of the negative pressure chamber 204 ranges from 20 to 100 mm. A width of the outward-extending cover is greater than that of the first part 301. Exemplarily, the width of the first part 301 at the upper portion of the negative pressure chamber 204 may be 15 mm, 25 mm, 35 mm and 40 mm, and the height of the negative pressure chamber 204 may be 20 mm, 50 mm, 70 mm and 100 mm.

In some other embodiments, in the front view, the first part 301 of the negative pressure chamber is shaped in a boss with a small upper portion and a large lower portion, and the second part 302 of the negative pressure chamber may also be shaped in a boss with a small upper portion and a large lower portion, so that, the projection region of the first part 301 is located within the projection region of the second part 302 in the direction parallel to the wafer.

Through the negative pressure chamber 204 formed by the first part 301 and the second part 302, coverage of a space above the wafer 201 may be enlarged, so that pressure of a wet region of the wafer 201 rotating to be below the negative pressure chamber 204 is smaller than that of other regions in the first chamber 202, thus the surface pressure of the drying agent is reduced relatively well, and the drying agent is easier to vaporize. Therefore, a capillary force during drying is reduced, and a probability of reducing pattern collapse is achieved.

The negative pressure chamber is structured like an annular wall formed by rotating the sectional view shown in FIG. 3 along a certain axis by a certain angle.

The negative pressure chamber may also be referred to as a vacuum chamber.

As shown in FIG. 3, the negative pressure chamber specifically includes two parts: one part is an upper cylinder with a smaller radius, while the other part is a lower shorter cylinder (outward-extending cover) with a larger radius. Such design makes it easier to form negative pressure in the negative pressure chamber.

In an embodiment, referring to FIG. 2, a second nozzle 207 may be further included in the first chamber 202 and configured to supply an inert gas.

In the embodiment of the disclosure, the inert gas may be, for example, nitrogen, helium, neon, argon, krypton, xenon, or the like, or a mixture thereof. The inert gas is inactive in chemical property and stable in structure. In the embodiment of the disclosure, the second nozzle 207 ensures that a surface of the wafer 201 is full of the inert gas without oxygen, and may also prevent generation of a watermark.

The first nozzle 203 may be in front of the second nozzle 207 in a rotation direction of the wafer 201.

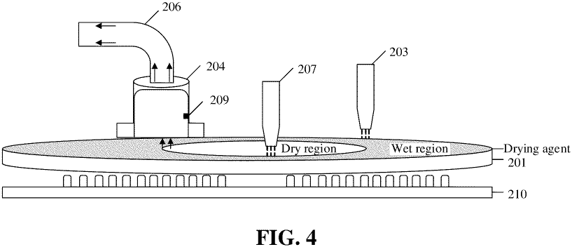

Specifically, for example, referring to FIG. 4, positions of the first nozzle 203 for the drying agent and the second nozzle 207 for the inert gas are related to the rotation direction of the wafer 201. A counter-clockwise rotation direction of the wafer 201 shown in FIG. 2 is taken as an example, distribution of positions of the first nozzle 203 and the second nozzle 207 in the rotation direction of the wafer 201 is as shown in FIG. 2, in which the first nozzle 203 is located in the front, i.e., closer to the negative pressure chamber 204 in the rotation direction of the wafer 201, and in front of the second nozzle 207, while the second nozzle 207 is located in the rear, i.e., back of the first nozzle 203 in the rotation direction of the wafer 201.

When the wafer 201 rotates clockwise, positions of the first nozzle 203 and the second nozzle 207 are interchanged. For example, point A is taken from the wafer 201, thus in the counter-clockwise rotation direction of the wafer 201 shown in FIG. 2, point A is sprayed by the first nozzle 203, then passes through the negative pressure chamber 204 to accelerate vaporization of the drying agent, and then is sprayed by the second nozzle 207 to accelerate drying.

In an embodiment, the apparatus may further include a controller (not shown in the figure).

The controller may be configured to control the vacuum pump 205 to vacuumize the negative pressure chamber 204 and control movement of the negative pressure chamber 204.

In an embodiment, as shown in FIG. 4, a vacuum gauge 209 may be arranged in the negative pressure chamber 204.

The controller may be further configured to adjust, according to a numerical value of the vacuum gauge 209, power of the vacuum pump 205.

Specifically, for example, the gas in the negative pressure chamber 204 is sucked by the vacuum pump to generate a negative pressure. As shown in FIG. 4, the vacuum gauge 209 is arranged in the negative pressure chamber 204. As shown in FIG. 4, power of the vacuum pump 205 may be adjusted according to a numerical value of the vacuum gauge 209, thereby controlling a vacuum degree stably. The vacuum degree of the negative pressure chamber 204 ranges from 0 to 50 kPa, and correspondingly, the pressure ranges from 101 to 61 kPa.

In an embodiment, as shown in FIG. 2, the pipeline 206 may include at least a corrugated pipe 206a or a straight pipe 206b.

The apparatus may further include a motor 208. For example, the motor 208 is a stepping motor.

The controller may be further configured to control the stepping motor 208 to drive at least the corrugated pipe 206a or the straight pipe 206b, to control the negative pressure chamber 204 to move on at least a plane parallel to the wafer 201 or a plane perpendicular to the wafer 201.

Specifically, for example, as shown in FIG. 4, during drying, a lower end face of the negative pressure chamber 204 is located at a height of 3 mm to 15 mm from a surface of the wafer 201, and the negative pressure chamber 204 moves in a range of 10 mm to 160 mm relative to a center of the wafer 201.

When the negative pressure chamber 204 is controlled to move horizontally during drying, a height of the negative pressure chamber 204 from the wafer 201 on the plane perpendicular to the wafer 201 is ensured to be in a certain range. For example, the height from the wafer ranges from 3 mm to 15 mm. Exemplarily, the height may be 3 mm, 8 mm, 10 mm and 15 mm. As such, pressure of a wet region of the wafer 201 rotating to be below the negative pressure chamber 204 is smaller than that of other regions in the first chamber 202, thus the surface pressure of the drying agent is reduced, and the drying agent is easier to vaporize. Therefore, a capillary force during drying is reduced, and a probability of reducing pattern collapse is achieved.

The movement of the negative pressure chamber 204 on the plane parallel to the wafer 201 (also referred to as forward and backward movement) refers to movement as follows: with the movement of the first nozzle 203 within an interval from the center of the wafer 201 to an edge of the wafer 201, the negative pressure chamber 204 may move from the center of the wafer 201 to the edge of the wafer 201 along with a spraying region of the first nozzle 203. A specific range of movement may be, for example, a range of a radius of the wafer plus 10 mm. That is, a range of the forward and backward movement, i.e., a range of movement of the negative pressure chamber 204 in a radius direction of the wafer 201 (such as a left-right direction shown in FIG. 4) is 10 mm to 160 mm from the center of the wafer, where all values in the range of movement are distances from the center of the wafer, and a maximum value of the range is “the radius of the wafer plus 10”.

The negative pressure chamber 204 and the first nozzle 203 are not connected to each other directly, and their movement are adjusted by respective control ends to finally ensure that the first nozzle 203 moves within the interval from the center of the wafer 201 to the edge of the wafer 201 and the negative pressure chamber 204 also moves within the interval from the center of the wafer 201 to the edge of the wafer 201.

In the embodiment of the disclosure, the vacuum pump or the like are made from anti-corrosion materials, and a waste treatment device is connected thereafter to treat vapor of the drying agent.

The negative pressure chamber, the pipeline (including the corrugated pipe and the straight pipe) and the vacuum pump may be brought into contact with an acid gas, and thus need anti-corrosion treatment. A normal stainless steel material may be used in combination with an anti-corrosion coating such as a polytetrafluoroethylene coating, a polypropylene coating, a polystyrene coating, or the like.

In an embodiment, as shown in FIG. 4, the apparatus may further include a dryer 210.

The dryer 210 may be arranged below the wafer 201 and configured to dry the wafer 201 by heat.

In an embodiment, the dryer 210 may include an LED lamp.

That is to say, the apparatus further includes an LED lamp arranged opposite to the wet region of the wafer 201 and configured to dry the wet region of the wafer 201 by heat. That is, the LED lamp configured to dry the wet region by heat is arranged in a projection region of the wet region of the wafer 201 in the direction perpendicular to the wafer 201.

In an embodiment, the controller may be further configured to:

adjust, according to a position of the first nozzle 203, change of temperature of the LED lamp, such that the LED lamp has a higher temperature in a specific region than at other positions, the specific region includes a projection region of the first nozzle 203 in the direction perpendicular to the wafer 201.

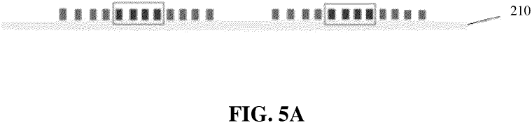

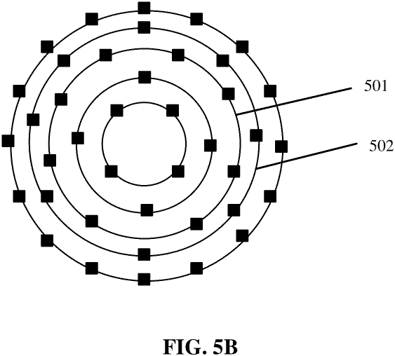

Specifically, for example, the dryer 210 in FIG. 4 may be an LED, i.e., an LED lamp, with a main purpose of heating the wafer 201. Referring to FIGS. 5A and 5B, LED lamps at a middle position (i.e., LED lamps shown in a rectangular box of FIG. 5A, LED lamps alternately on a circular ring 501 and a circular ring 502 of FIG. 5B), i.e., LED lamps at a position (i.e., the specific region) opposite to the spraying region of the first nozzle 203 (spraying IPA for example) in the direction perpendicular to the wafer 201, have higher temperature than that of LED lamps at other positions, such that the drying agent is heated more, which helps the drying agent to reach the boiling point faster when it passes through the negative pressure chamber 204, to accelerate vaporization. In summary, in the embodiment of the disclosure, a corresponding LED lamp is controlled to change its temperature with change of the spraying region of the drying agent, i.e., with change of the position of the first nozzle 203, to ensure that the LED lamp corresponding to the position of the first nozzle 203 has a higher temperature.

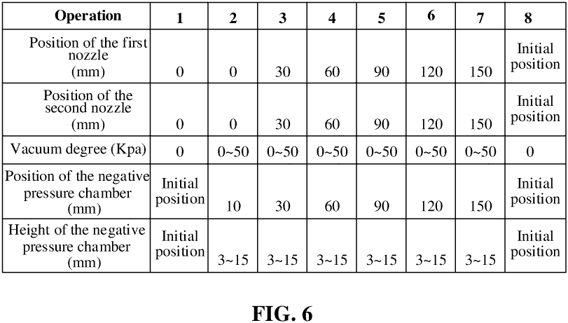

In the embodiment of the disclosure, a specific method for controlling processing of a wafer by the controller includes, for example, the following processing operations, as shown in FIG. 6.

In a first operation, the first nozzle sprays at the center of the wafer, to spray a drying agent on the wafer, to replace a treating fluid in a wafer pattern. In such case, the vacuum pump is not started, a vacuum degree is 0 kPa, and the negative pressure chamber is located at an initial position.

Semiconductor wet clean usually cleans the wafer 201 with a chemical, then cleans the chemical with a treating fluid including water for example, and finally replaces the treating fluid with a drying agent (IPA) to perform drying.

In the first operation, the drying agent is sprayed on the wafer 201 at a central point of the wafer 201 to replace the treating fluid in the wafer 201. Then, the first nozzle 203 starts moving towards an edge of the wafer 201, and drying is performed.

In a second operation, the first nozzle is located at the center of the wafer, the second nozzle is opened and the vacuum pump is started, and the negative pressure chamber is located at a preset height above the wafer, for example, at a height of 3 to 15 mm above the wafer.

In third to seventh operations, the first nozzle moves from the center of the wafer to the edge of the wafer, and the position of the second nozzle, the vacuum degree, and the position of the negative pressure chamber are set as pre-configured, for example, configured as shown in FIG. 6, thereby implementing finer operations of drying the wafer.

In FIG. 6, the position of the negative pressure chamber, i.e., a movement position of the negative pressure chamber 204 on a plane parallel to the wafer 201, does not include a height position relative to the wafer 201. In second to seventh operations, the height of the negative pressure chamber 204 remains unchanged. That is to say, the height of the negative pressure chamber 204 needs not to be adjusted during drying, and is set according to a preset height of 3 to 15 mm only.

It should be noted that all the positions in FIG. 6 are positions relative to the center of the wafer 201 on the plane parallel to the wafer 201, and the initial position is a position where the negative pressure chamber is placed when it is not used. Heights of the first nozzle 203 and the second nozzle 207 relative to the wafer 201 usually range from 5 mm to 40 mm (requirement of a height in a working state).

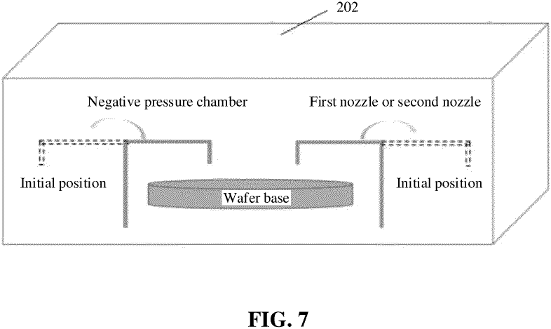

The initial positions of elements are located on two sides of a base of the wafer, and the first nozzle, the second nozzle, and a support pipeline below the negative pressure chamber is rotationally movable. As shown in FIG. 7, the initial position (home) only needs to make the first nozzle, the second nozzle and the negative pressure chamber located on one side of the wafer when they are not used, and are not necessarily positions after rotation by 180 degrees. Their respective vertical spindles are rotatable, and cantilever structures are telescopic.

Specifically, for example, referring to FIG. 6:

In a third operation, the first nozzle 203 is controlled to be located at a distance of 30 mm from the center of the wafer 201, the second nozzle 207 is controlled to be located at a distance of 30 mm from the center of the wafer 201, the vacuum degree is controlled to be in the range of 0 to 50 kPa, and the negative pressure chamber 204 is controlled to be located at a distance of 30 mm from the center of the wafer 201.

In a fourth operation, the first nozzle 203 is controlled to be located at a distance of 60 mm from the center of the wafer 201, the second nozzle 207 is controlled to be located at a distance of 60 mm from the center of the wafer 201, the vacuum degree is controlled to be in the range of 0 to 50 kPa, and the negative pressure chamber 204 is controlled to be located at a distance of 60 mm from the center of the wafer 201.

In a fifth operation, the first nozzle 203 is controlled to be located at a distance of 90 mm from the center of the wafer 201, the second nozzle 207 is controlled to be located at a distance of 90 mm from the center of the wafer 201, the vacuum degree is controlled to be in the range of 0 to 50 kPa, and the negative pressure chamber 204 is controlled to be located at a distance of 90 mm from the center of the wafer 201.

In a sixth operation, the first nozzle 203 is controlled to be located at a distance of 120 mm from the center of the wafer 201, the second nozzle 207 is controlled to be located at a distance of 120 mm from the center of the wafer 201, the vacuum degree is controlled to be in the range of 0 to 50 kPa, and the negative pressure chamber 204 is controlled to be located at a distance of 120 mm from the center of the wafer 201.

In a seventh operation, the first nozzle 203 is controlled to be located at a distance of 150 mm from the center of the wafer 201, the second nozzle 207 is controlled to be located at a distance of 150 mm from the center of the wafer 201, the vacuum degree is controlled to be in the range of 0 to 50 kPa, and the negative pressure chamber 204 is controlled to be located at a distance of 150 mm from the center of the wafer 201.

In an eighth operation, positions and heights of the first nozzle 203, the second nozzle 207 and the negative pressure chamber 204 are controlled to make the first nozzle 203, the second nozzle 207 and the negative pressure chamber 204 return to their initial positions respectively, and the vacuum pump 205 is stopped.

In the above drying operation, preset parameters of the machine need to be set according to actual needs, including, but are not limited to important parameters in the table shown in FIG. 6. Each of the parameters needs to be set correspondingly according to features, positions, etc., of the elements such as the first nozzle 203, the second nozzle 207, the negative pressure chamber 204, or the like.

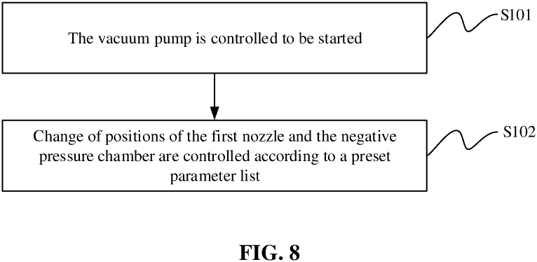

In summary, referring to FIG. 8, an embodiment of the disclosure provides a method for controlling processing of a wafer, which is implemented based on the apparatus for processing a wafer and includes the following operations.

In operation S101, the vacuum pump of the apparatus for processing a wafer provided in the embodiment of the disclosure is controlled to be started.

In operation S102, change of positions of the first nozzle, the second nozzle and the negative pressure chamber of the apparatus for processing a wafer provided in the embodiment of the disclosure is controlled according to a preset parameter list.

In an embodiment, the method may further include the following operations.

Change of the position of the second nozzle of the apparatus for processing a wafer provided in the embodiment of the disclosure is controlled according to the preset parameter list.

In an embodiment, the method may further include the following operations.

A vacuum degree of the negative pressure chamber of the apparatus for processing a wafer provided in the embodiment of the disclosure is controlled according to the preset parameter list.

In an embodiment, the change of the position of the negative pressure chamber may include at least movement of the negative pressure chamber in a direction parallel to the wafer, or movement of the negative pressure chamber in a direction perpendicular to the wafer.

In the preset parameter list provided in the embodiment of the disclosure, as shown in FIG. 6, the same parameter of the same object in different operations may have different values or the same value. For example, the position (specifically referring to a position in a plane parallel to the wafer) of the negative pressure chamber, the position of the first nozzle and the position of the second nozzle have different specific values in different operations, but a value of a height of the negative pressure chamber in the whole drying process may remain unchanged.

Correspondingly, an embodiment of the disclosure provides an apparatus for controlling processing of a wafer (i.e., the controller), including a first unit and a second unit.

The first unit is configured to control the vacuum pump of the apparatus for processing a wafer provided in the embodiment of the disclosure to be started.

The second unit is configured to control, according to a preset parameter list, change of positions of the first nozzle, the second nozzle and the negative pressure chamber of the apparatus for processing a wafer provided in the embodiment of the disclosure.

In an embodiment, the second unit may be further configured to:

control, according to the preset parameter list, change of the position of the second nozzle of the apparatus for processing a wafer provided in the embodiment of the disclosure.

In an embodiment, the second unit may be configured to:

control, according to the preset parameter list, a vacuum degree of the negative pressure chamber of the apparatus for processing a wafer provided in the embodiment of the disclosure.

In an embodiment, the change of the position of the negative pressure chamber may include at least movement of the negative pressure chamber in a direction parallel to the wafer, or movement of the negative pressure chamber in a direction perpendicular to the wafer.

It should be noted that in the embodiments of the disclosure, division of the units is schematic, only a logical function division, and other division manners may be adopted during practical implementation. Furthermore, each functional unit in each embodiment of the disclosure may be integrated into a processing unit, each unit may also physically exist independently, and two or more than two units may also be integrated into a unit. The integrated unit may be implemented in form of hardware or in form of hardware plus software functional units.

When the integrated unit is implemented in form of a software function unit and sold or used as an independent product, it may be stored in a computer-readable storage medium. Based on such an understanding, the technical solutions of the disclosure substantially or parts making contributions to the related art, or all or part of the technical solutions may be embodied in form of a software product, and the computer software product is stored in a storage medium, including several instructions configured to enable a computer device (which may be a personal computer, a server, a network device, or the like) or a processor to execute all or part of operations of the method in each embodiment of the disclosure. The abovementioned storage medium includes various media capable of storing program codes such as a U disk, a mobile hard disk, a Read Only Memory (ROM), a Random Access Memory (RAM), a magnetic disk, an optical disk, or the like.

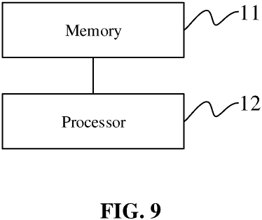

An embodiment of the disclosure provides a computing device (i.e., the controller), which may be specifically a desktop computer, a portable computer, a smart phone, a tablet computer, a Personal Digital Assistant (PDA), or the like. As shown in FIG. 9, the computing device may include a memory 11 and a processor (such as a Central Processing Unit (CPU)) 12, and may further include an input/output (I/O) device, or the like (not shown in the figure). The input device may include a keyboard, a mouse, a touch screen, or the like. The output device may include a display device, such as a Liquid Crystal Display (LCD), a Cathode Ray Tube (CRT), or the like.

The memory 11 may include a ROM and a RAM, and provides program instructions and data stored in the memory to the processor. In the embodiment of the disclosure, the memory may be configured to store a program for any method provided in the embodiment of the disclosure.

The processor 12 calls the program instructions stored in the memory. The processor is configured to execute, according to the obtained program instructions, any method provided in the embodiment of the disclosure.

An embodiment of the disclosure also provides a computer program product or a computer program, including computer instructions stored in a computer-readable storage medium. A processor of a computer device reads the computer instructions from the computer-readable storage medium. The processor executes the computer instructions to enable the computer device to execute any method in the above embodiments. The program product may adopt a readable medium or any combination of multiple readable media. The readable medium may be a readable signal medium or a readable storage medium. For example, the readable storage medium may be, but is not limited to an electrical, magnetic, optical, electromagnetic, infrared or semiconductor system, apparatus, or device, or any combination thereof. More specific examples (non-exhaustive list) of the readable storage medium include an electrical connector with one or more wires, a portable disk, a hard disk, a RAM, a ROM, an Erasable Programmable ROM (EPROM) (or a flash memory), an optical fiber, a portable Compact Disc ROM (CD-ROM), an optical storage device, a magnetic storage device, or any proper combination thereof.

An embodiment of the disclosure provides a computer-readable storage medium, configured to store computer program instructions used by the apparatus provided in the embodiment of the disclosure, and including a program for executing any method provided in the embodiment of the disclosure. The computer-readable storage medium may be a non-transitory computer-readable medium.

The computer-readable storage medium may be any available medium or data storage device accessible for a computer, including, but not limited to, a magnetic memory (such as a floppy disk, a hard disk, a magnetic tape, a Magneto-Optical (MO) disk, or the like), an optical memory (such as a Compact Disc (CD), a Digital Video Disk (DVD), a Blue-ray Disk (BD), a High-definition Versatile Disc (HVD), or the like), and a semiconductor memory (such as a ROM, an EPROM, an Electrically EPROM (EEPROM), a non-volatile memory (NAND FLASH), a Solid State Drive (SSD)).

Those skilled in the art should understand that the embodiment of the disclosure may be provided as a method, a system, or a computer program product. Therefore, forms of a pure hardware embodiment, a pure software embodiment or an embodiment combining software with hardware may be used in the disclosure. Furthermore, form of a computer program product implemented on one or more computer-available storage media (including, but not limited to, a hard disk memory, an optical memory, or the like) including computer-available program codes may be used in the disclosure.

The disclosure is described with reference to flowcharts and/or block diagrams of the method, device (system) and computer program product according to the embodiments of the disclosure. It should be understood that each flow and/or block in the flowcharts and/or block diagrams and combination of the flows and/or blocks in the flowcharts and/or block diagrams may be implemented by computer program instructions. These computer program instructions may be provided to a general purpose computer, a special purpose computer, an embedded processor, or a processor of another programmable data processing device to produce a machine, such that when executed by the processor of the computer or another programmable data processing device, the instructions produce a device for implementing functions specified in one or more flows of the flowchart and/or one or more blocks of the block diagram.

These computer program instructions may also be stored in a computer-readable storage medium capable of guiding the computer or another programmable data processing device to operate in a specific manner, such that an article of manufacture including an instruction device may be generated by the instructions stored in the computer-readable memory, the instruction device implements functions specified in one or more flows of the flowchart and/or one or more blocks of the block diagram.

These computer program instructions may also be loaded onto a computer or other programmable data processing devices, such that a series of operational steps are performed on the computer or other programmable devices to produce a computerimplemented process, so that the instructions executed on the computer or other programmable devices provide operations for implementing functions specified in one or more flows of the flowchart and/or one or more blocks of the block diagram.

It is apparent that those skilled in the art may make various modifications and transformations to the disclosure without departing from the spirit and scope of the disclosure. Therefore, when these modifications and transformations of the disclosure fall within the scope of the claims of the disclosure and equivalent technologies thereof, then the disclosure is also intended to include these modifications and transformations.

1. An apparatus for processing a wafer, comprising:
a first chamber;
a first nozzle arranged in the first chamber and configured to spray a drying agent to the wafer;
a negative pressure chamber located in the first chamber; and
a vacuum pump located outside of the first chamber and connected with the negative pressure chamber through a pipeline,
wherein the negative pressure chamber is arranged in a direction perpendicular to the wafer, and a gas in the negative pressure chamber is sucked by the vacuum pump through the pipeline to generate a negative pressure in the first chamber, so as to reduce a surface pressure of the drying agent sprayed onto the wafer by the first nozzle.

2. The apparatus of claim 1, wherein a second nozzle is further arranged in the first chamber and configured to supply an inert gas, and
the first nozzle is in front of the second nozzle in a rotation direction of the wafer.

3. The apparatus of claim 1, wherein the negative pressure chamber comprises a first part and a second part, the first part is located above the second part in the direction perpendicular to the wafer, and a projection region of the first part is located within a projection region of the second part in a direction parallel to the wafer.

4. The apparatus of claim 1, further comprising:
a controller configured to control the vacuum pump to vacuumize the negative pressure chamber and control movement of the negative pressure chamber.

5. The apparatus of claim 4, wherein a vacuum gauge is arranged in the negative pressure chamber, and
the controller is further configured to adjust, according to a numerical value of the vacuum gauge, power of the vacuum pump.

6. The apparatus of claim 4, wherein the pipeline comprises at least a corrugated pipe or a straight pipe.

7. The apparatus of claim 6, further comprising a stepping motor,
wherein the controller is further configured to control the stepping motor to drive at least the corrugated pipe or the straight pipe, to control the negative pressure chamber to move on at least a plane parallel to the wafer or a plane perpendicular to the wafer.

8. The apparatus of claim 4, further comprising:
a dryer arranged below the wafer and configured to dry the wafer by heat.

9. The apparatus of claim 8, wherein the dryer comprises a Light Emitting Diode (LED) lamp.

10. The apparatus of claim 9, wherein the controller is further configured to:
adjust, according to a position of the first nozzle, change of temperature of the LED lamp, such that the LED lamp has a higher temperature in a specific region than at other positions, wherein the specific region comprises a projection region of the first nozzle in the direction perpendicular to the wafer.

11. A method for controlling processing of a wafer, implemented based on the apparatus of claim 1, the method comprising:
controlling the vacuum pump of the apparatus to be started; and
controlling, according to a preset parameter list, change of positions of the first nozzle, a second nozzle and the negative pressure chamber of the apparatus.

12. The method of claim 11, further comprising:
controlling, according to the preset parameter list, change of the position of the second nozzle of the apparatus.

13. The method of claim 11, further comprising:
controlling, according to the preset parameter list, a vacuum degree of the negative pressure chamber of the apparatus.

14. The method of claim 11, wherein the change of the position of the negative pressure chamber comprises at least movement of the negative pressure chamber in a direction parallel to the wafer, or movement of the negative pressure chamber in a direction perpendicular to the wafer.

15. The method of claim 11, further comprising:
adjusting, according to a numerical value of a vacuum gauge arranged in the negative pressure chamber, power of the vacuum pump.

16. The method of claim 11, further comprising:
controlling a stepping motor of the apparatus, to control the negative pressure chamber to move on at least the plane parallel to the wafer or a plane perpendicular to the wafer.

17. The method of claim 11, further comprising:
adjusting, according to a position of the first nozzle, change of temperature of a Light Emitting Diode (LED) lamp of a dryer of the apparatus, such that the LED lamp has a higher temperature in a specific region than at other positions, wherein the specific region comprises a projection region of the first nozzle in the direction perpendicular to the wafer.

18. An electronic device, comprising:
a memory configured to store program instructions; and
a processor configured to call the program instructions stored in the memory, to execute, according to an obtained program, a method for controlling processing of a wafer, implemented based on the apparatus of claim 1, the method comprising:
controlling the vacuum pump of the apparatus to be started; and
controlling, according to a preset parameter list, change of positions of the first nozzle, a second nozzle and the negative pressure chamber of the apparatus.

19. A non-transitory computer-readable storage medium, having stored thereon computer-executable instructions, wherein the computer-executable instructions enable a computer to execute a method for controlling processing of a wafer, implemented based on the apparatus of claim 1, the method comprising:
controlling the vacuum pump of the apparatus to be started; and
controlling, according to a preset parameter list, change of positions of the first nozzle, a second nozzle and the negative pressure chamber of the apparatus.
